(19) United States
(12) Patent Application Publication
(10) Pub. No.: US 2017/0069878 A1
(43) Pub. Date: Mar. 9, 2017

(54) OLED DISPLAY APPARATUS AND METHOD FOR PREPARING THE SAME

(71) Applicant: BOE TECHNOLOGY GROUP CO., LTD., Beijing (CN)

(72) Inventors: Ming Che HSIEH, Beijing (CN); Hejin WANG, Beijing (CN); Yuanzheng GUO, Beijing (CN); Lu LIU, Beijing (CN); Chunyan XIE, Beijing (CN); Baoming CAI, Beijing (CN)

(73) Assignee: BOE TECHNOLOGY GROUP CO., LTD., Beijing (CN)

(21) Appl. No.: 15/146,253

(22) Filed: May 4, 2016

(30) Foreign Application Priority Data
Sep. 9, 2015 (CN) 201510569895.5

(51) Int. Cl. H01L 51/52; H01L 51/56; H01L 51/00

(52) U.S. Cl. CPC H01L 51/5275; H01L 51/0097; H01L 51/56; H01L 2251/5338

(57) ABSTRACT

Disclosed are an OLED display apparatus and a method for preparing the same. The OLED display apparatus includes a flexible substrate, an array layer disposed on the flexible substrate, an organic light-emitting layer disposed on the array layer, a package layer disposed on the organic light-emitting layer, and a base film disposed on a side of the flexible substrate facing away from the array layer, a plurality of protruded microstructures being provided on the side of the flexible substrate facing away from the array layer.

### TECHNICAL FIELD

Embodiments of the present disclosure relate to an OLED display apparatus and a method for preparing the same.

### BACKGROUND

Displays using OLED (Organic Light-Emitting Diode) are novel flat panel display devices, and their future is bright owing to their advantages such as simple procedure, low cost, fast response, easiness to achieve color display and large screen display, low power consumption, easiness to match with an integrated circuit driver, great brightness, broad application range of operating temperature, small volume and easiness to achieve flexible display.

### SUMMARY

Embodiments of the present disclosure provide an OLED display apparatus, comprising a flexible substrate, an array layer disposed on the flexible substrate, an organic light-emitting layer disposed on the array layer, a package layer disposed on the organic light-emitting layer, and a base film disposed on a side of the flexible substrate facing away from the array layer, a plurality of protruded microstructures being provided on the side of the flexible substrate facing away from the array layer.

Embodiments of the present disclosure further provide a method for preparing an OLED display apparatus, comprising: forming a plurality of protruded microstructures on one side of the flexible substrate; forming an array layer, an organic light-emitting layer and a package layer sequentially on the other side of the flexible substrate.

### BRIEF DESCRIPTION OF THE DRAWINGS

In order to clearly illustrate the technical solutions of the embodiments of the present disclosure, the drawings of the embodiments are briefly described below. Apparently, the drawings described below relate to only some embodiments of the present disclosure and thus are not limitative of the present disclosure.

FIG. 1 is a schematic structural view of an OLED display apparatus.

FIG. 2 is a schematic structural view of an OLED display apparatus according to embodiments of the present disclosure.

FIG. 3 is a flow chart of a method for preparing an OLED display apparatus according to embodiments of the present disclosure.

FIGS. 4a-4d are structural schematic views of the various steps for preparing an OLED display apparatus.

### REFERENCE SIGNS

01—base film; 02—flexible substrate; 03—array layer; 04—organic light-emitting layer; 05—package layer, 1—base film; 2—flexible substrate; 21—microstructure; 3—array layer; 4—organic light-emitting layer; 5—package layer; 6—base substrate; 7—laser beam.

### DETAILED DESCRIPTION

To make clearer the objects, technical solutions and advantages of the embodiments of the present disclosure, a clear and full description of the technical solutions of the embodiments of the present disclosure will be made with reference to the accompanying drawings of the embodiments of the present disclosure. Apparently, the described embodiments are just part rather than all of the embodiments of the present disclosure. Based on the embodiments of the present disclosure described, all the other embodiments obtained by a person of ordinary skill in the art, without any creative labor, fall within the scope of protection of the present disclosure.

The overall light exiting efficiency of an OLED display apparatus is not high. As shown in FIG. 1, FIG. 1 is a schematic structural view of an OLED display apparatus, mainly comprising: a base film 01, a flexible substrate 02, an array layer 03, an organic light-emitting layer 04 and a package layer 05, wherein when the light emitted from the organic light-emitting layer 04 illuminates on the base film 01, part of the light will emit towards the interior of the OLED display apparatus after total reflection by the base film 01, and the light transmission path is as shown by the arrows in FIG. 1, as a result of which, the conventional OLED display apparatus generally has a light exiting efficiency of only about 20%.

A method for improving the light exiting efficiency of an OLED display apparatus comprises: attaching a lens array film to a luminous substrate, and using a photonic crystal structure layer, a high refractive index substrate, etc. to enhance the light extraction efficiency of the OLED display apparatus. While improving light extraction efficiency, this method, however, introduces some problems, for example: movement of exiting light spectra, change of electrical properties, reduction of flexible bending ability, etc., and the process is more complex and at a higher cost.

Embodiments of the present disclosure provide an OLED display apparatus and a method for preparing the same to improve the light extraction efficiency of the OLED display apparatus.

Embodiments of the present disclosure provide an OLED display apparatus, comprising: a flexible substrate, an array layer disposed on the flexible substrate, an organic light-emitting layer disposed on the array layer, a package layer disposed on the organic light-emitting layer, and a base film disposed on the side of the flexible substrate facing away from the array layer, a plurality of protruded microstructures being provided on the side of the flexible substrate facing away from the array layer.

As for the OLED display apparatus according to embodiments of the present disclosure, by providing a plurality of microstructures protruded in a direction away from the array layer on the side of the flexible substrate facing away from the array layer, the incident angle of light on the base film after coming out from the array layer can be changed, so that the incident angle on the base film is less than the total reflection critical angle of the base film, the occurrence of total reflection of incident light on the base film is reduced, the light emitted from the organic light-emitting layer is refracted from the side of the base film facing away from the flexible substrate as much as possible, and the light exiting efficiency of the base film is improved.

Hence, the OLED display apparatus according to embodiments of the present disclosure can improve the light extraction efficiency of the OLED display apparatus.

In some embodiments, the plurality of microstructures and the flexible substrate are integral, which facilitates making.

In some embodiments, the plurality of microstructures are distributed uniformly.

In some embodiments, each hemispherical microstructure has a radian of 1 rad to 10 rad.

In some embodiments, each of the microstructures is semi-ellipsoidal.

Embodiments of the present disclosure further provide a method for preparing an OLED display apparatus, comprising: forming a plurality of protruded microstructures on one side of the flexible substrate; forming an array layer, an organic light-emitting layer and a package layer sequentially on the other side of the flexible substrate.

A display apparatus is prepared by the method for preparing an OLED display apparatus according to embodiments of the present disclosure. By forming a plurality of microstructures protruded in a direction away from the array layer on the side of the flexible substrate facing away from the array layer, the incident angle of light on the base film after coming out from the array layer may be changed, the occurrence of total reflection of incident light on the base film is reduced, and the light exiting efficiency of the base film is improved.

Hence, the method for preparing an OLED display apparatus according to embodiments of the present disclosure can improve the light extraction efficiency of the OLED display apparatus, and the preparation process is simple.

In some embodiments, forming a plurality of protruded microstructures on one side of the flexible substrate specifically comprises: forming a plurality of recesses on a side of a base substrate; forming a flexible substrate on the side of the base substrate where the plurality of recesses are formed, a plurality of microstructures corresponding to and matchable with the plurality of recesses one by one being formed on the side of the flexible substrate facing toward the base substrate.

In some embodiments, the above preparation method further comprises: peeling off the base substrate from the flexible substrate; providing a base film on the side of the flexible substrate where the plurality of the microstructures are formed.

In some embodiments, forming a plurality of protruded microstructures on one side of the flexible substrate specifically comprises: forming a plurality of recesses on a side of the base film; forming a flexible substrate on the side of the base film where the plurality of recesses are formed, a plurality of microstructures corresponding to and matchable with the plurality of recesses one by one being formed on the side of the flexible substrate facing toward the base film.

In some embodiments, each of the microstructures is protruded in a direction away from the array layer.

In some embodiments, each of the recesses is recessed towards the base film.

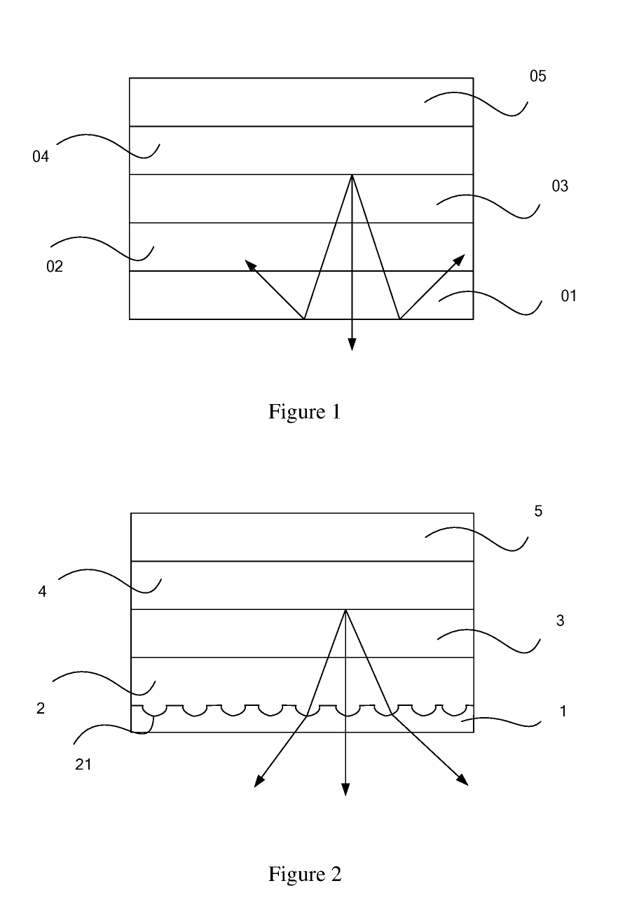

FIG. 2 is a schematic structural view of an OLED display apparatus according to embodiments of the present disclosure; the OLED display apparatus according to the present embodiments comprises: a flexible substrate 2, an array layer 3 disposed on the flexible substrate 2, an organic light-emitting layer 4 disposed on the array layer 3, a package layer 5 disposed on the organic light-emitting layer 4 and a base film 1 disposed on a side of the flexible substrate 2 facing away from the array layer 3, a plurality of microstructures 21 protruded in a direction away from the array layer 3 being provided on the side of the flexible substrate 2 facing away from the array layer 3.

With the OLED display apparatus according to embodiments of the present disclosure, by providing a plurality of microstructures 21 protruded in a direction away from the array layer 3 on the side of the flexible substrate 2 facing away from the array layer 3, the incident angle of light on the base film 1 after coming out from the array layer 3 can be changed, so that the incident angle on the base film 1 is less than the total reflection critical angle of the base film 1, the occurrence of total reflection of incident light on the base film 1 is reduced, the light emitted from the organic light-emitting layer 4 is refracted from the side of the base film 1 facing away from the flexible substrate 2 as much as possible, and the light exiting efficiency of the base film 1 is improved.

Hence, the OLED display apparatus according to embodiments of the present disclosure can improve the light extraction efficiency of the OLED display apparatus.

In one embodiment, the plurality of microstructures 21 and the flexible substrate are integral, which facilitates making. In another embodiment, the plurality of microstructures 21 and the flexible substrate are prepared separately and then, for example, are bonded together.

In one embodiment, the plurality of microstructures 21 are distributed uniformly.

The specific shape of each of the above microstructures 21 may have many options.

In one alternative embodiment, for example, each microstructure 21 is hemispherical. Further, for example, each hemispherical microstructure 21 has a radian of 1 rad to 10 rad, for example: 1 rad, 2 rad, 3 rad, 4 rad, 5 rad, 6 rad, 7 rad, 8 rad, 9 rad, 10 rad, etc.

In another alternative embodiment, each microstructure 21 is semi-ellipsoidal.

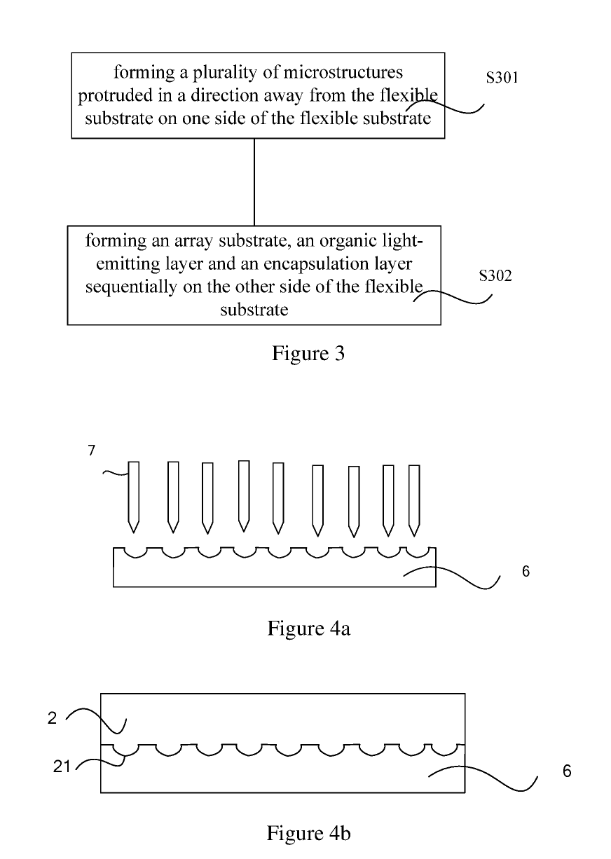

FIG. 3 is a flow chart of a method for preparing an OLED display apparatus according to embodiments of the present disclosure. Embodiments of the present disclosure further provide a method for preparing an OLED display apparatus, comprising the steps of Step S301 and Step S302.

Step S301: forming a plurality of microstructures 21 protruded in a direction away from the flexible substrate 2 on one side of the flexible substrate 2;

Step S302: forming an array layer 3, an organic light-emitting layer 4 and a package layer 5 sequentially on the other side of the flexible substrate 2.

The display apparatus is prepared by the method for preparing an OLED display apparatus according to the present embodiments. By forming a plurality of microstructures 21 protruded in a direction away from the array layer 3 on the side of the flexible substrate 2 facing away from the array layer 3, the incident angle of light on the base film 1 after coming out from the array layer 3 may be changed, the occurrence of total reflection of incident light on the base film 1 is reduced, and the light exiting efficiency of the base film 1 is improved.

Hence, the method for preparing an OLED display apparatus according to embodiments of the present disclosure can improve the light extraction efficiency of the OLED display apparatus, and the preparation process is simple.

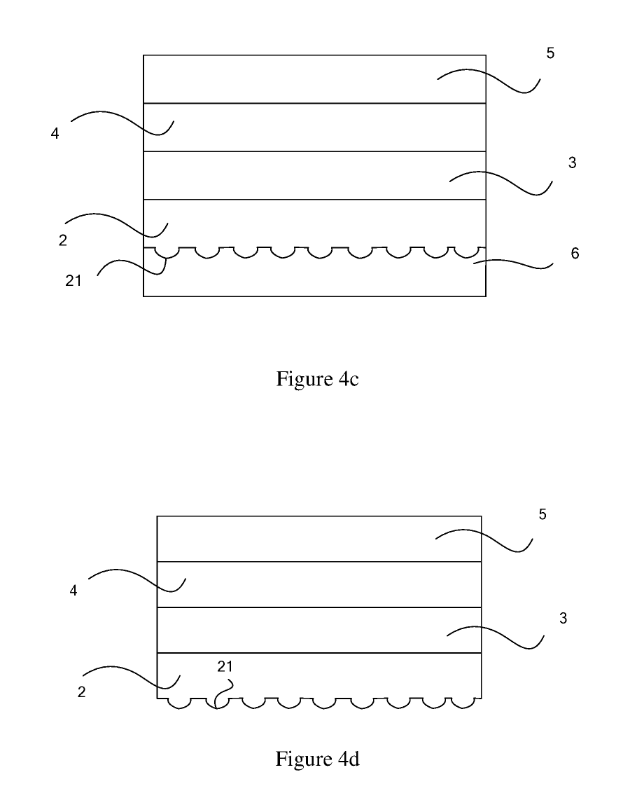

FIGS. 4a-4d are schematic structural views of an OLED display apparatus according to embodiments of the present disclosure. In one embodiment, Step S301: forming a plurality of microstructures 21 protruded in a direction away from the flexible substrate 2 on one side of the flexible substrate 2, for example, may be carried out specifically as follows.

A plurality of recesses recessed towards the base substrate 6 is formed on a side of the base substrate 6; for example, such recesses may be formed on a side of the base substrate 6 by a laser beam 7. The structure formed is as shown in FIG. 4a.

A flexible substrate 2 is formed on the side of the base substrate 6 where the plurality of recesses are formed, a plurality of microstructures 21 corresponding to and matchable with the plurality of recesses one by one being formed on the side of the flexible substrate 2 facing toward the base substrate 6. For example, the material for forming the flexible substrate 2 is typically liquid; the material for forming the flexible substrate 2 is injected to the base substrate 6 provided with recesses, and after curing, a plurality of microstructures 21 will be formed on the side of the flexible substrate 2 facing toward the base substrate 6. The structures formed are as shown in FIG. 4b.

Subsequently, Step S302 is carried out. An array layer 3, an organic light-emitting layer 4 and a package layer 5 are sequentially formed on the other side of the flexible substrate 2. The structure formed is as shown in FIG. 4c.

Further, the above preparation method further comprises: peeling off the base substrate 6 from the flexible substrate 2; the structure of the OLED display apparatus formed after the step is as shown in FIG. 4d.

A base film 1 is attached to the side of the flexible substrate 2 provided with a plurality of microstructures 21. The structure of the OLED display apparatus formed after the step is as shown in FIG. 2.

In another embodiment, Step S301: forming a plurality of microstructures 21 protruded in a direction away from the flexible substrate on a side of the flexible substrate 2, which, for example, may be carried out specifically as follows.

A plurality of recesses recessed towards the base film 1 is formed on a side of the base film 1; a flexible substrate 2 is formed on the side of the base film 1 where the plurality of recesses are formed, a plurality of microstructures 21 corresponding to and matchable with the plurality of recesses one by one being formed on the side of the flexible substrate 2 facing toward the base film 1.

Hence, in some embodiments, each of the microstructures is a protrusion.

In some embodiments, for example, the cross-section of the protrusion is semi-circular or semi-ellipsoidal.

In some embodiments, for example, the plurality of microstructures occupies no less than 50% of an area of the flexible substrate. The greater the area of the flexible substrate the microstructures occupy, the more the light exiting efficiency will be improved. Therefore, the area of the flexible substrate the microstructures occupy may be greater than 60%, greater than 70%, greater than 80%, or greater than 90%.

In some embodiments, for example, each of the microstructures may have a size of 100 nm to 1 mm. The size of each of the microstructures may be any one size within the range of 100 nm to 1 mm, for example, 200 nm, 300 nm, 400 nm, 500 nm, 600 nm, 700 nm, 1 micron, 10 microns, 100 microns, 500 microns, etc. In the present application, the size of the microstructure refers to the average value of the two smaller extents (sizes) of each microstructure in a three-dimensional space. For example, when the microstructure is a protrusion (the cross-section being a semi-ellipsoid), the size of the microstructure may be the average value of the long axis a and the short axis b of the semi-ellipsoid, i.e., (a+b)/2. For example, when the microstructure is a protrusion (the cross-section being a semi-sphere), the size of the microstructure may be the diameter of the semi-sphere.

The above are merely exemplary embodiments of the present disclosure, and are not intended to limit the scope of protection of the present disclosure, which is yet determined by the appended claims.

The present application claims the priority of the Chinese patent application No. 201510569895.5 submitted on Sep. 9, 2015, and the content disclosed in the above Chinese patent application is incorporated herein by reference as part of the present application.

What is claimed is:

1. An organic light-emitting device (OLED) display apparatus, comprising:
a flexible substrate,
an array layer disposed on the flexible substrate,
an organic light-emitting layer disposed on the array layer,
a package layer disposed on the organic light-emitting layer, and
a base film disposed on a side of the flexible substrate facing away from the array layer,
wherein a plurality of protruded microstructures is provided on the side of the flexible substrate facing away from the array layer.

2. The OLED display apparatus according to claim 1, wherein the plurality of microstructures and the flexible substrate are integral.

3. The OLED display apparatus according to claim 1, wherein the plurality of microstructures are distributed uniformly.

4. The OLED display apparatus according to claim 1, wherein each of the microstructures is hemispherical.

5. The OLED display apparatus according to claim 4, wherein each hemispherical microstructure has a radian of 1 rad to 10 rad.

6. The OLED display apparatus according to claim 1, wherein each of the microstructures is semi-ellipsoidal.

7. The OLED display apparatus according to claim 2, wherein each of the microstructures is hemispherical.

8. The OLED display apparatus according to claim 2, wherein each of the microstructures is semi-ellipsoidal.

9. The OLED display apparatus according to claim 1, wherein each of the microstructures is a protrusion.

10. The OLED display apparatus according to claim 9, wherein a cross-section of the protrusion is semi-circular or semi-ellipsoidal.

11. The OLED display apparatus according to claim 1, wherein the plurality of microstructures occupy no less than 50% of an area of the flexible substrate.

12. The OLED display apparatus according to claim 1, wherein each of the microstructures has a size of 100 nm to 1 mm.

13. The OLED display apparatus according to claim 1, wherein each of the microstructures is protruded in a direction away from the array layer.

14. A method for preparing an organic light-emitting diode (OLED) display apparatus, comprising:
forming a plurality of protruded microstructures on one side of the flexible substrate; and
forming an array layer, an organic light-emitting layer and a package layer sequentially on the other side of the flexible substrate.

15. The method of claim 14, wherein forming the plurality of protruded microstructures on one side of the flexible substrate comprises:
forming a plurality of recesses on a side of a base substrate;
forming a flexible substrate on the side of the base substrate where the plurality of recesses are formed, wherein a plurality of microstructures corresponding to and matchable with the plurality of recesses one by one is formed on a side of the flexible substrate facing toward the base substrate.

16. The method of claim 14, wherein each of the microstructures is protruded in a direction away from the array layer.

17. The method of claim 15, further comprising:
peeling off the base substrate from the flexible substrate; and
providing a base film on the side of the flexible substrate where the plurality of the microstructures are formed.

18. The method of claim 14, wherein forming the plurality of protruded microstructures on one side of the flexible substrate comprises:
forming a plurality of recesses on a side of the base film; and
forming a flexible substrate on the side of the base film where the plurality of recesses are formed, wherein a plurality of microstructures corresponding to and matchable with the plurality of recesses one by one is formed on a side of the flexible substrate facing toward the base film.

19. The method of claim 18, wherein each of the recesses is recessed towards the base film.
